(19) United States
(12) Patent Application Publication
(10) Pub. No.: US 2016/0056040 A1
(43) Pub. Date: Feb. 25, 2016

(54) METHOD FOR MANUFACTURING SILICON CARBIDE SEMICONDUCTOR DEVICE

(71) Applicant: SUMITOMO ELECTRIC INDUSTRIES, LTD., Osaka-shi (JP)

(72) Inventors: So TANAKA, Osaka-shi (JP); Shunsuke YAMADA, Osaka-shi (JP)

(73) Assignee: Sumitomo Electric Industries, Ltd., Osaka-shi (JP)

(21) Appl. No.: 14/779,900

(22) PCT Filed: Mar. 4, 2014
(86) PCT No.: PCT/JP2014/055389

§ 371 Date: Sep. 24, 2015

(30) Foreign Application Priority Data
Apr. 26, 2013 (JP) 2013-093687

(51) Int. Cl. H01L 21/04; H01L 29/16; H01L 29/45

(52) U.S. Cl. CPC H01L 21/0485; H01L 29/45; H01L 29/1608

(57) ABSTRACT

A silicon carbide layer having a main surface and including a p-type region and an n-type region in contact with the p-type region is prepared. A metal layer in contact with the p-type region and the n-type region at the main surface is formed. The p-type region, the n-type region, and the metal layer are annealed. The step of forming a metal layer includes the steps of forming a first region in contact with the p-type region and the n-type region at the main surface and forming a second region arranged to be in contact with a surface of the first region opposite to a surface in contact with the main surface. The first region has an aluminum element and a silicon element. The second region has a titanium element.

### TECHNICAL FIELD

The present invention relates to a method for manufacturing a silicon carbide semiconductor device, and more particularly to a method for manufacturing a silicon carbide semiconductor device having an electrode capable of achieving a lowered contact resistance.

### BACKGROUND ART

In order to allow a semiconductor device to be high in breakdown voltage and low in loss, silicon carbide has recently increasingly been adopted as a material forming a semiconductor device. Silicon carbide is a wide band gap semiconductor greater in band gap than silicon which has conventionally widely been used as a material forming a semiconductor device. Therefore, by adopting silicon carbide as a material forming a semiconductor device, a higher breakdown voltage and lowering in ON resistance of a semiconductor device can be achieved. A semiconductor device containing silicon carbide as a material is also advantageous in that lowering in characteristics when it is used in a high temperature environment is less than in a semiconductor device containing silicon as a material.

As a method for manufacturing an electrode in a semiconductor device containing silicon carbide, for example, Japanese Patent Laying-Open No. 2012-253291 (PTD 1) describes formation of an electrode through heat treatment in an argon gas after a metal film is formed on a silicon carbide substrate. Japanese Patent Laying-Open No. 2012-146838 (PTD 2) describes a contact electrode provided on a silicon carbide substrate, which contains Al atoms, Ti atoms, and Si atoms. Japanese Patent Laying-Open No. 2012-99599 (PTD 3) describes a method of forming an ohmic contact electrode by forming a Ti film on a silicon carbide substrate, forming an Al film on the Ti film, forming an Si film on the Al film, and thereafter carrying out annealing with laser beams.

Osamu Nakatsuka et al., “Low Resistance TiAl Ohmic Contacts with Multi-Layered Structure for p-Type 4H—SiC,” Materials Transactions, Vol. 43, No. 7, 2002, pp. 1684-1688 (NPD 1) describes influence by an Al concentration on electrical characteristics of a TiAl electrode establishing low-resistance ohmic contact with p-type silicon carbide. According to this document, electrical characteristics of the TiAl electrode are affected not by the number of TiAl layers but by a concentration of Al in the TiAl electrode.

Z. Q. Guan et al., “Phase formation during ball milling and subsequent thermal decomposition of Ti—Al—Si powder blends,” Journal of Alloys and Compounds, 252, 1997, pp. 245-251 (NPD 2) describes investigation about phase formation of a TiAlSi powdery mixture. According to this document, a decomposition process in two stages in a mechanically alloyed TiAlSi alloy has been found.

### CITATION LIST

### Patent Document

PTD 1: Japanese Patent Laying-Open No. 2012-253291
PTD 2: Japanese Patent Laying-Open No. 2012-146838
PTD 3: Japanese Patent Laying-Open No. 2012-99599

### Non Patent Document

NPD 1: Osamu Nakatsuka et al., “Low Resistance TiAl Ohmic Contacts with Multi-Layered Structure for p-Type 4H—SiC,” Materials Transactions, Vol. 43, No. 7, 2002, pp. 1684-1688
NPD 2: Z. Q. Guan et al., “Phase formation during ball milling and subsequent thermal decomposition of Ti—Al—Si powder blends,” Journal of Alloys and Compounds, 252, 1997, pp. 245-251

### SUMMARY OF INVENTION

### Technical Problem

When an electrode in contact with a silicon carbide layer is formed with the methods described in Japanese Patent Laying-Open No. 2012-253291 (PTD 1), Japanese Patent Laying-Open No. 2012-146838 (PTD 2), and Japanese Patent Laying-Open No. 2012-99599 (PTD 3), a low contact resistance to an n-type region in the silicon carbide layer is obtained, however, a contact resistance to a p-type region in the silicon carbide layer has not sufficiently been low in some cases.

The present invention was made in view of the problems above, and an object thereof is to provide a method for manufacturing a silicon carbide semiconductor device having an electrode capable of realizing a low contact resistance to both of a p-type region and an n-type region in a silicon carbide layer.

### Solution to Problem

The present inventor has conducted dedicated studies about a cause of a contact resistance between an electrode containing Ti (titanium), Al (aluminum), and Si (silicon) and a p-type region in a silicon carbide layer not being sufficiently low in a case that the electrode is formed on the silicon carbide layer, and obtained the finding below and found the present invention. As a result of detailed investigation of a silicon carbide semiconductor device high in contact resistance and a silicon carbide semiconductor device low in contact resistance, it has been found that composition (a concentration) of Al at an interface between an electrode of the silicon carbide semiconductor device high in contact resistance and a silicon carbide layer is lower than composition (a concentration) of Al at an interface between an electrode of the silicon carbide semiconductor device low in contact resistance and a silicon carbide layer.

The cause of a low concentration of Al at the interface between the electrode and the silicon carbide layer is estimated as follows. After a metal layer containing Ti, Al, and Si is formed on a silicon carbide layer, the metal layer is annealed at a temperature around 1000° C. Then, an electrode establishing ohmic contact with the silicon carbide layer is formed. A eutectic point of AlSi is around 577° C. and a melting point of Al is around 660° C. Therefore, during a period of temperature increase of the metal layer from a room temperature to 1000° C., liquefaction of AlSi starts at a temperature around 577° C. and liquefaction of Al starts at a temperature around 660° C. Therefore, it is expected that, in a temperature range from around 577° C. to around 1000° C., Al evaporates from a surface of the electrode and some Al separates from the electrode, and consequently a concentration of Al at the interface between the electrode and the silicon carbide layer lowers.

As Al separates and a concentration of Al at the interface lowers, a concentration of Al which diffuses into the silicon carbide layer also lowers. Al functions as a p-type dopant for silicon carbide, and increase in concentration of a dopant in a p-type region brings about a low contact resistance. Therefore, as a concentration of Al at the interface between the electrode and the silicon carbide layer is lower, a contact resistance between the electrode and the p-type region in the silicon carbide layer is higher. As a result of dedicated studies conducted by the inventors, the inventors have found that, by forming a metal layer including a first region containing an Al element and an Si element and a second region containing a Ti element and formed on the first region and thereafter annealing the metal layer, an electrode achieving prevented loss of Al and having a low contact resistance to both of a p-type region and an n-type region can be formed. Namely, by arranging the second region containing the Ti element which is highest in melting point among Ti, Al, and Si (Ti having a melting point around 1670° C. and Si having a melting point around 1414° C.) on the first region containing the Al element, the second region functions as a Al separation prevention layer.

A method for manufacturing a silicon carbide semiconductor device according to the present invention has the following steps. A silicon carbide layer having a main surface and including a p-type region and an n-type region in contact with the p-type region is prepared. A metal layer in contact with the p-type region and the n-type region at the main surface is formed. After the step of forming a metal layer, the p-type region, the n-type region, and the metal layer are annealed. The step of forming a metal layer includes the steps of forming a first region in contact with the p-type region and the n-type region at the main surface and forming a second region arranged to be in contact with a surface of the first region opposite to a surface in contact with the main surface. The first region has an aluminum element and a silicon element. The second region has a titanium element.

### Advantageous Effects of Invention

As is clear from the description above, according to the present invention, a method for manufacturing a silicon carbide semiconductor device having an electrode capable of realizing a low contact resistance to both of a p-type region and an n-type region in a silicon carbide layer can be provided.

### BRIEF DESCRIPTION OF DRAWINGS

FIG. 1 is a schematic cross-sectional view schematically showing a construction of a silicon carbide semiconductor device manufactured with a method for manufacturing a silicon carbide semiconductor device according to one embodiment of the present invention.

FIG. 2 is a flowchart schematically showing the method for manufacturing a silicon carbide semiconductor device according to one embodiment of the present invention.

FIG. 3 is a schematic cross-sectional view schematically showing a first step in the method for manufacturing a silicon carbide semiconductor device according to one embodiment of the present invention.

FIG. 4 is a schematic cross-sectional view schematically showing a second step in the method for manufacturing a silicon carbide semiconductor device according to one embodiment of the present invention.

FIG. 5 is a schematic cross-sectional view schematically showing a third step in the method for manufacturing a silicon carbide semiconductor device according to one embodiment of the present invention.

FIG. 6 is a schematic cross-sectional view schematically showing a fourth step in the method for manufacturing a silicon carbide semiconductor device according to one embodiment of the present invention.

FIG. 7 is a flowchart for illustrating details of a metal layer forming step.

FIG. 8 is a schematic cross-sectional view schematically showing a fifth step in the method for manufacturing a silicon carbide semiconductor device according to one embodiment of the present invention.

FIG. 9 is a flowchart for illustrating details of a first region forming step.

FIG. 10 is an enlarged view of a construction of a region A in FIG. 8.

FIG. 11 is an enlarged view of a first modification of the construction of region A in FIG. 8.

FIG. 12 is a flowchart for illustrating details of a second region forming step.

FIG. 13 is an enlarged view of a second modification of the construction of region A in FIG. 8.

FIG. 14 is an enlarged view of a third modification of the construction of region A in FIG. 8.

FIG. 15 is a schematic cross-sectional view schematically showing a sixth step in the method for manufacturing a silicon carbide semiconductor device according to one embodiment of the present invention.

FIG. 16 is a diagram showing relation between an element contained in the metal layer and a temperature.

### DESCRIPTION OF EMBODIMENTS

An embodiment of the present invention will be described hereinafter with reference to the drawings. It is noted that, in the drawings below, the same or corresponding elements have the same reference characters allotted and description thereof will not be repeated. In addition, regarding crystallographic denotation herein, an individual orientation, a group orientation, an individual plane, and a group plane are shown in [ ], < >, ( ), and { }, respectively. Moreover, a crystallographically negative index is normally expressed by a number with a bar “-” thereabove, however, a negative sign herein precedes a number. In expressing an angle, a system in which a total azimuth angle is defined as 360 degrees is employed.

Overview of an embodiment of the present invention will initially be described in (1) to (8) below.

(1) A method for manufacturing a silicon carbide semiconductor device 1 according to an embodiment has the following steps. A silicon carbide layer 10 having a main surface 10a and including a p-type region 18 and an n-type region 14 in contact with p-type region 18 is prepared. A metal layer 16 in contact with p-type region 18 and n-type region 14 at main surface 10a is formed. After the step of forming metal layer 16, p-type region 18, n-type region 14, and metal layer 16 are annealed. The step of forming metal layer 16 includes the steps of forming a first region 16a in contact with p-type region 18 and n-type region 14 at main surface 10a and forming a second region 16b arranged in contact with a surface 16a5 of first region 16a opposite to a surface 16a4 in contact with main surface 10a. First region 16a has an aluminum element and a silicon element. Second region 16b has a titanium element.

According to the method for manufacturing silicon carbide semiconductor device 1 according to the present embodiment, after metal layer 16 in which second region 16b containing the titanium element is arranged on first region 16a having the aluminum element and the silicon element is formed, metal layer 16 is annealed. Therefore, since metal layer 16 is annealed while aluminum is covered with titanium, evaporation of aluminum and separation thereof from metal layer 16 can be prevented. Consequently, a silicon carbide semiconductor device having an electrode capable of realizing a low contact resistance to both of the p-type region and the n-type region in the silicon carbide layer can be manufactured.

(2) In the method for manufacturing silicon carbide semiconductor device 1 according to the embodiment, preferably, first region 16a further contains the titanium element. Thus, a silicon carbide semiconductor device having an electrode capable of realizing a lower contact resistance to both of the p-type region and the n-type region in the silicon carbide layer can be manufactured.

(3) In the method for manufacturing silicon carbide semiconductor device 1 according to the embodiment, preferably, the step of forming first region 16a includes the following steps. A first layer 16a1 being in contact with p-type region 18 and n-type region 14 and containing the titanium element is formed. A second layer 16a2 being in contact with first layer 16a1 and containing the aluminum element is formed. A third layer 16a3 being in contact with second layer 16a2 and containing the silicon element is formed. Since third layer 16a3 containing the silicon element is formed on first layer 16a1 containing the aluminum element, evaporation of aluminum can efficiently be suppressed. Consequently, a contact resistance between p-type region 18 and the electrode can be lowered.

(4) In the method for manufacturing silicon carbide semiconductor device 1 according to the embodiment, preferably, first layer 16a1 has a thickness not smaller than 140 angstroms and not greater than 340 angstroms. Thus, a contact resistance between the electrode and the n-type region and a contact resistance between the electrode and the p-type region can effectively be lowered.

(5) In the method for manufacturing silicon carbide semiconductor device 1 according to the embodiment, preferably, second layer 16a2 has a thickness not smaller than 190 angstroms and not greater than 390 angstroms. Thus, a contact resistance between the electrode and the p-type region can effectively be lowered.

(6) In the method for manufacturing silicon carbide semiconductor device 1 according to the embodiment, preferably, third layer 16a3 has a thickness not smaller than 230 angstroms and not greater than 430 angstroms. Thus, a contact resistance between the electrode and the n-type region can effectively be lowered.

(7) In the method for manufacturing silicon carbide semiconductor device 1 according to the embodiment, preferably, second region 16b further contains the silicon element. Thus, oxidation of titanium contained in second region 16b can be suppressed. As a result of oxidation of silicon, silicon dioxide is produced, however, silicon dioxide can readily be removed with hydrofluoric acid.

(8) In the method for manufacturing silicon carbide semiconductor device 1 according to the embodiment, preferably, the step of forming second region 16b includes the following steps. A fourth layer 16b1 being in contact with first region 16a and containing the titanium element is formed. A fifth layer 16b2 being in contact with fourth layer 16b1 and containing the silicon element is formed. Thus, oxidation of titanium contained in second region 16b can effectively be suppressed.

(9) In the method for manufacturing silicon carbide semiconductor device 1 according to the embodiment, preferably, the step of forming second region 16b includes the step of forming a layer containing a titanium silicide alloy. Thus, oxidation of titanium contained in second region 16b can effectively be suppressed.

(10) In the method for manufacturing silicon carbide semiconductor device 1 according to the embodiment, preferably, the step of forming second region 16b includes the step of forming a layer containing a titanium carbon alloy. Thus, oxidation of titanium contained in second region 16b can effectively be suppressed.

(11) In the method for manufacturing silicon carbide semiconductor device 1 according to the embodiment, preferably, second region 16b has a thickness not smaller than 200 angstroms and not greater than 300 angstroms. When second region 16b has a thickness T_{b} in a range not smaller than 200 angstroms and not greater than 300 angstroms, evaporation of aluminum contained in first region 16a can effectively be suppressed and productivity of silicon carbide semiconductor device 1 can be improved.

An embodiment of the present invention will now be described in further detail.

Initially, a construction of a metal oxide semiconductor field effect transistor (MOSFET) representing the silicon carbide semiconductor device according to one embodiment of the present invention will be described.

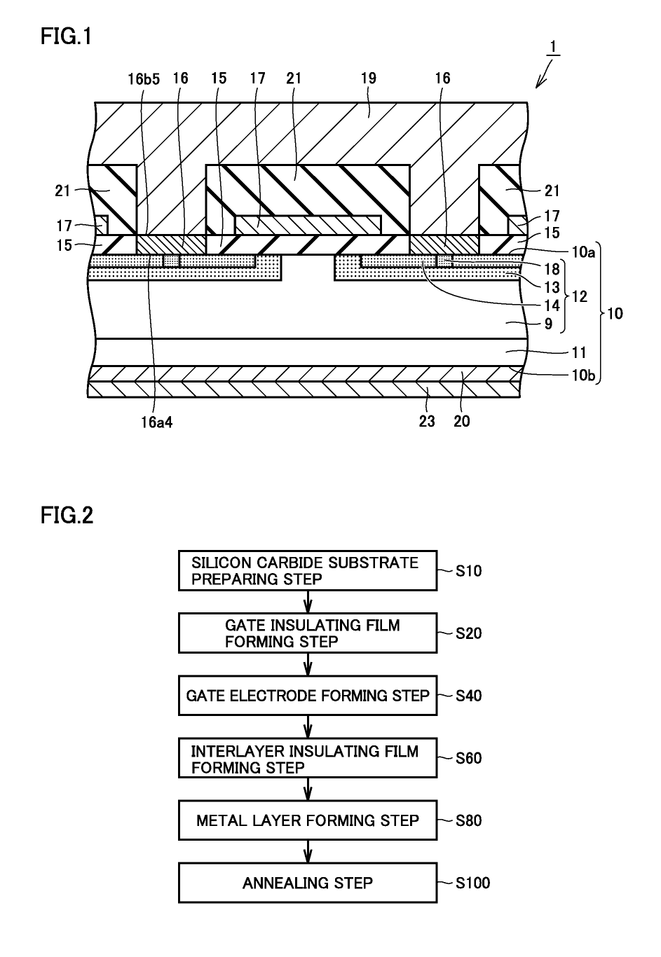

Referring to FIG. 1, a MOSFET 1 mainly has silicon carbide layer 10, a gate insulating film 15, a gate electrode 17, a source contact electrode 16, a source interconnection 19, a drain electrode 20, and an interlayer insulating film 21. Silicon carbide layer 10 has a first main surface 10a and a second main surface 10b opposite to first main surface 10a. Silicon carbide layer 10 mainly includes a single-crystal substrate 11 and an epitaxial layer 12. Epitaxial layer 12 mainly includes a drift layer 9, a p body 13, an n+ source region 14, and a p+ region 18.

Single-crystal substrate 11 is composed, for example, of hexagonal silicon carbide having a poly type of 4H. Single-crystal substrate 11 contains such an impurity as N (nitrogen) at a high concentration and has an n-type. Epitaxial layer 12 is a layer resulting from epitaxial growth of silicon carbide. Epitaxial layer 12 is formed on one main surface of single-crystal substrate 11, for example, to a thickness approximately from 10 to 15 μm.

Drift layer 9 included in epitaxial layer 12 contains such an impurity as N (nitrogen) and has an n conductivity type. Such an impurity as nitrogen contained in drift layer 9 is higher in concentration than an n-type impurity contained in single-crystal substrate 11. A concentration of such an impurity as nitrogen contained in drift layer 9 is, for example, around 5×10¹⁵ cm⁻³. First main surface 10a may be a surface angled off by approximately at most 10°, for example, relative to a {0001} plane.

P body 13 is a region having a p conductivity type. P body 13 is formed in epitaxial layer 12 to be in contact with first main surface 10a. P body 13 contains such an impurity as Al (aluminum) or B (boron). A concentration of an impurity contained in p body 13 is, for example, around 1×10¹⁷ cm⁻³.

N+ source region 14 is a region having the n conductivity type. N+ source region 14 is formed in p body 13 to be in contact with first main surface 10a and to be surrounded by p body 13. N+ source region 14 contains such an impurity as P (phosphorus) at a concentration higher than that of the n-type impurity contained in drift layer 9, for example, at a concentration of 1×10²⁰ cm⁻³.

P+ region 18 is a region having the p conductivity type. P+ region 18 is in contact with n+ source region 14, first main surface 10a, and p body 13. P+ region 18 is formed to pass through n+ source region 14 from first main surface 10a to p body 13. P+ region 18 contains such an impurity as Al or B at a concentration higher than that of the impurity contained in p body 13, for example, at a concentration of 1×10²⁰ cm⁻³.

Gate insulating film 15 is formed on first main surface 10a of epitaxial layer 12 so as to be in contact with first main surface 10a and extend from an upper surface of one n+ source region 14 to an upper surface of the other n+ source region 14. Gate insulating film 15 is composed, for example, of silicon dioxide.

Gate electrode 17 is arranged to be in contact with gate insulating film 15, so as to extend over from one n+ source region 14 to the other n+ source region 14. Gate electrode 17 is composed of polysilicon doped with an impurity or such a conductor as Al.

Source contact electrode 16 has first surface 16a4 in contact with first main surface 10a and second surface 16b5 opposite to first surface 16a4. Source contact electrode 16 is in contact with gate insulating film 15, p+ region 18, and n+ source region 14. Source contact electrode 16 contains, for example, a titanium (Ti) element, an aluminum (Al) element, and a silicon (Si) element. Preferably, when a concentration profile of Ti in source contact electrode 16 is measured along a direction of normal to first main surface 10a, a region where a Ti concentration is highest is located close to second surface 16b5, relative to a position intermediate between first surface 16a4 and second surface 16b5.

Source interconnection 19 is formed to be in contact with source contact electrode 16, and formed, for example, of such a conductor as Ti/Al. Source interconnection 19 is electrically connected to n+ source region 14 through source contact electrode 16. Source interconnection 19 is formed to cover interlayer insulating film 21 which will be described later.

Drain electrode 20 is formed to be in contact with second main surface 10b of silicon carbide layer 10. Drain electrode 20 may be constructed similarly, for example, to source contact electrode 16, or may be formed of another material such as Ni having the n-type, which can establish ohmic contact with single-crystal substrate 11. Drain electrode 20 is electrically connected to single-crystal substrate 11. A backside pad electrode 23 composed, for example, of Ni/Au is formed to be in contact with drain electrode 20.

Interlayer insulating film 21 is formed to be in contact with gate insulating film 15 and gate electrode 17 and to cover gate electrode 17. Interlayer insulating film 21 is composed, for example, of silicon dioxide, and electrically isolates gate electrode 17 from the outside. A passivation film (not shown) may be formed on interlayer insulating film 21.

An operation of MOSFET 1 will now be described. While a voltage not higher than a threshold value is applied to gate electrode 17, that is, in an off state, a portion between p body 13 and epitaxial layer 12 located directly under gate insulating film 15 is reverse biased and rendered non-conducting. When a positive voltage is applied to gate electrode 17, an inversion layer is formed in a channel region around a portion of contact of p body 13 with gate insulating film 15. Consequently, n+ source region 14 and epitaxial layer 12 are electrically connected to each other and a current flows between a source electrode 22 and drain electrode 20.

A method for manufacturing MOSFET 1 in the present embodiment will now be described.

Initially, a silicon carbide substrate preparing step (S10: FIG. 2) is performed. Specifically, initially, epitaxial layer 12 is formed with epitaxial growth on one main surface of single-crystal substrate 11 composed of silicon carbide. Epitaxial layer 12 can be formed, for example, by adopting a gas mixture of SiH₄ (silane) and C₃H₈ (propane) as a source material gas. For example, such an impurity as N (nitrogen) is introduced in epitaxial layer 12. Thus, epitaxial layer 12 containing an impurity at a concentration lower than that of an impurity contained in single-crystal substrate 11 is formed to be in contact with single-crystal substrate 11. As above, silicon carbide layer 10 having first main surface 10a and second main surface 10b opposite to first main surface 10a is prepared.

Then, an oxide film composed of silicon dioxide is formed, for example, with chemical vapor deposition (CVD) on first main surface 10a of silicon carbide layer 10. After a resist is applied onto the oxide film, the resist is exposed and developed to form a resist film (not shown) having an opening in a region corresponding to a desired shape of p body 13. With the resist film serving as a mask, the oxide film is partially removed, for example, through reactive ion etching (RIE). Thus, a mask layer formed from the oxide film having an opening pattern is formed on epitaxial layer 12. Thereafter, after the resist film is removed, with this mask layer serving as a mask, such a p-type impurity as Al is introduced through ion implantation into first main surface 10a of silicon carbide layer 10. Thus, p body 13 is formed in epitaxial layer 12. Then, after the oxide film which has been used as the mask is removed, a mask layer having an opening in a region corresponding to a desired shape of n+ source region 14 is formed. Thereafter, with the mask layer serving as a mask, such an impurity as P (phosphorus) is introduced through ion implantation into epitaxial layer 12, to thereby form n+ source region 14. Then, a mask layer having an opening in a region corresponding to a desired shape of p+ region 18 is formed. With the mask layer serving as a mask, such an impurity as Al or B is introduced through ion implantation into epitaxial layer 12, to thereby form p+ region 18. P+ region 18 is formed to be in contact with n+ source region 14, first main surface 10a, and p body 13.

Then, heat treatment for activating an impurity introduced through ion implantation is carried out. Specifically, epitaxial layer 12 into which ions have been implanted is heated to a temperature around 1700° C., for example, in an Ar (argon) atmosphere and held for approximately 30 minutes. As above, silicon carbide layer 10 having first main surface 10a and including p+ region 18 and n+ source region 14 in contact with the p+ region is prepared.

Referring to FIG. 5, a gate insulating film forming step (S20: FIG. 2) is performed. Specifically, first main surface 10a of silicon carbide layer 10 including p+ region 18 and n+ source region 14 is subjected to thermal oxidation. Thermal oxidation can be carried out, for example, by heating to approximately 1300° C. and holding for approximately 40 minutes in an oxygen atmosphere. Thus, a thermal oxidation film 15 composed of silicon dioxide is formed on first main surface 10a (for example, to a thickness of approximately 50 nm).

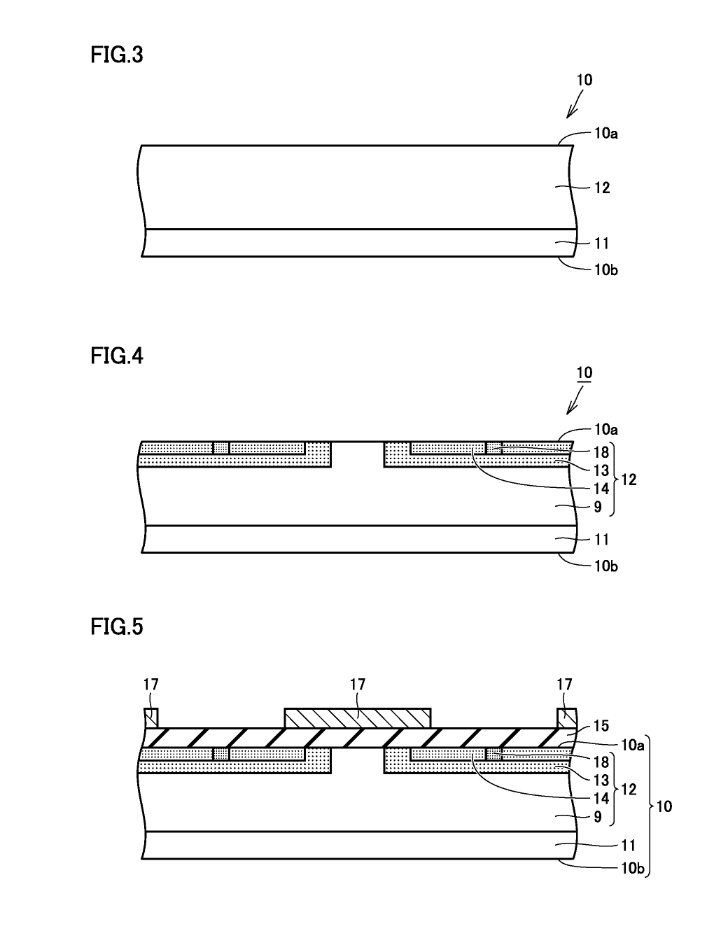

Then, a gate electrode forming step (S40: FIG. 3) is performed. Specifically, for example, gate electrode 17 composed of polysilicon doped with an impurity or of Al is formed to extend over from one n+ source region 14 to the other n+ source region 14 and to be in contact with thermal oxidation film 15. When polysilicon is adopted as a source material for gate electrode 17, polysilicon can contain phosphorus at a high concentration exceeding 1×10²⁰ cm⁻³.

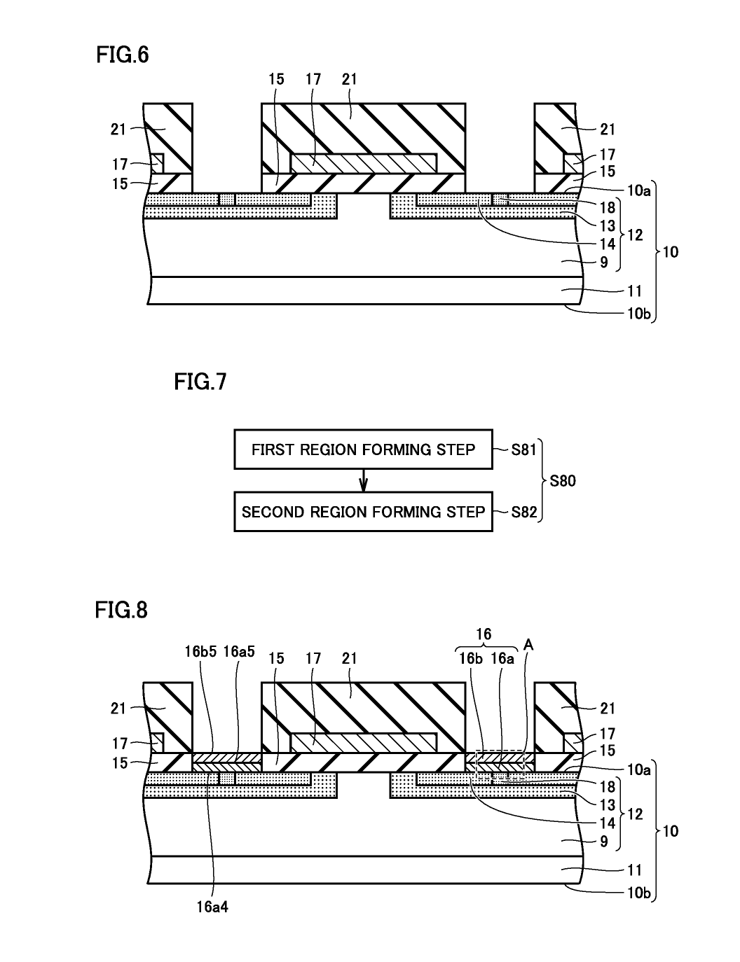

Then, referring to FIG. 6, an interlayer insulating film forming step (S60: FIG. 2) is performed. In this step, interlayer insulating film 21 composed, for example, of silicon dioxide is formed with CVD so as to be in contact with thermal oxidation film 15 and to cover gate electrode 17. Then, an opening portion of a source electrode portion is formed. Specifically, a part of interlayer insulating film 21 and thermal oxidation film 15 is removed so as to expose a part of p+ region 18 and n+ source region 14.

Then, a metal layer forming step (S80: FIG. 2) is performed. Specifically, metal layer 16 in contact with p+ region 18 and n+ source region 14 is formed, for example, with vapor deposition or sputtering. The metal layer forming step includes a first region forming step (S81: FIG. 7) and a second region forming step (S82: FIG. 7). Referring to FIG. 8, in the first region forming step (S81: FIG. 7), first region 16a in contact with p+ region 18, n+ source region 14, and gate insulating film 15 is formed. First region 16a has an aluminum element and a silicon element. Then, second region 16b arranged to be in contact with surface 16a5 of first region 16a opposite to first surface 16a4 in contact with first main surface 10a of silicon carbide layer 10 is formed. Second region 16b may be in contact with gate insulating film 16b. Second region 16b has a titanium element. Preferably, second region 16b is made of a titanium layer in contact with the entire surface 16a5 of first region 16a. Preferably, in the step of forming second region 16b, a layer containing a titanium silicon alloy is formed. In the step of forming second region 16b, a layer including a layer containing a titanium carbon alloy may be formed. Preferably, second region 16b has thickness T_{b} not smaller than 200 angstroms (20 nm) and not greater than 300 angstroms (30 nm). Second region 16b may have thickness T_{b} not smaller than 200 angstroms and not greater than 1000 angstroms.

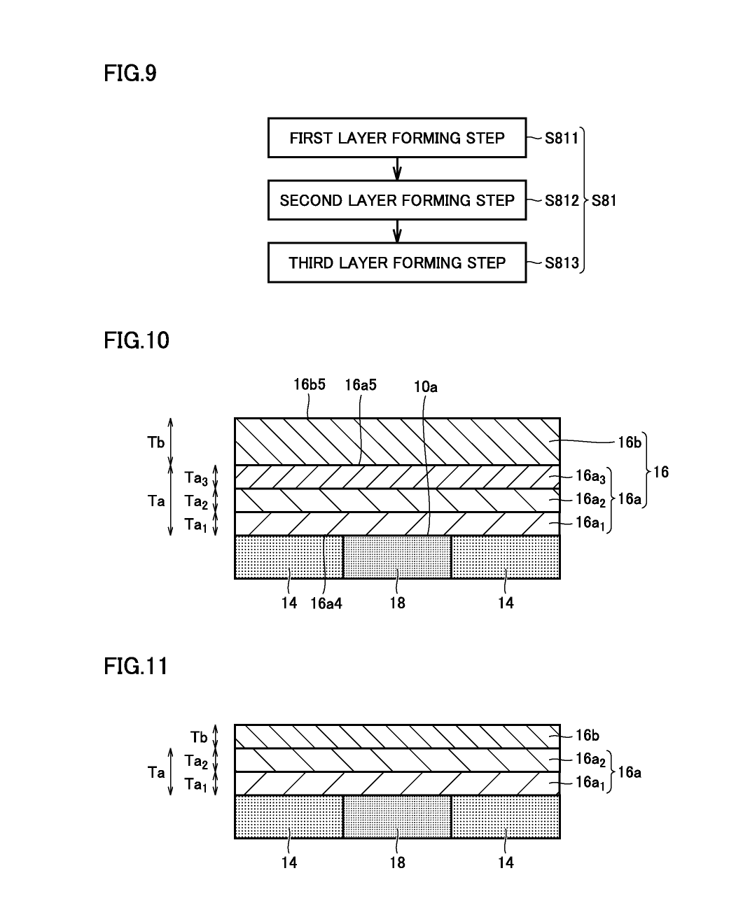

Referring to FIG. 9, the first region forming step (S81) may include a first layer forming step (S811), a second layer forming step (S812), and a third layer forming step (S813). Specifically, referring to FIG. 10, first layer 16a1 being in contact with p+ region 18 and n+ source region 14 and containing a titanium element is formed. Preferably, first layer 16a1 is a titanium layer. Preferably, first layer 16a1 has a thickness Tₐ₁ not smaller than 140 angstroms (14 nm) and not greater than 340 angstroms (34 nm). Then, second layer 16a2 being in contact with first layer 16a1 and containing an aluminum element is formed. Preferably, second layer 16a2 is an aluminum layer. Preferably, second layer 16a2 has a thickness Tₐ₂ not smaller than 190 angstroms and not greater than 390 angstroms. Then, third layer 16a3 being in contact with second layer 16a2 and containing a silicon element is formed. Preferably, third layer 16a3 is a silicon layer. Preferably, third layer 16a3 has a thickness Tₐ₃ not smaller than 230 angstroms and not greater than 430 angstroms. Then, second region 16b is formed to be in contact with third layer 16a3.

Referring to FIG. 10, first layer 16a1 in first region 16a is, for example, a titanium layer, second layer 16a2 is an aluminum layer, and third layer 16a3 is a silicon layer. Second region 16b is made, for example, of a titanium layer. Second region 16b may be made of a TiSi (titanium silicide) alloy or of a TiC (titanium carbon) alloy. When second region 16b is made of the TiSi alloy, second region 16b can be formed, for example, by simultaneously vapor depositing Ti and Si.

Referring to FIG. 11, first region 16a may have a two-layered structure of first layer 16a1 and second layer 16a2. When first region 16a has the two-layered structure, first layer 16a1 and second layer 16a2 may be an aluminum layer and a silicon layer, respectively, or may be a silicon layer and an aluminum layer, respectively.

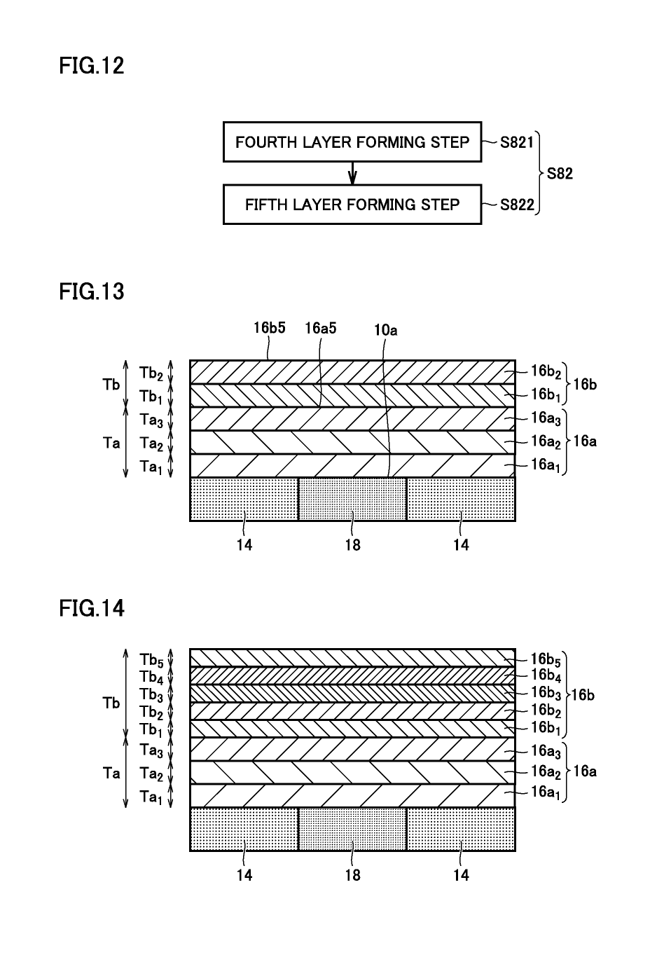

Referring to FIG. 12, the second region forming step (S81) may include a fourth layer forming step (S821) and a fifth layer forming step (S822). Specifically, referring to FIG. 13, in the second region forming step, fourth layer 16b1 being in contact with surface 16a5 of first region 16a and containing a titanium element is formed. Fifth layer 16b2 being in contact with fourth layer 16b1 and containing a silicon element is formed. Preferably, fourth layer 16b1 is a titanium layer and fifth layer 16b2 is a silicon layer. Fourth layer 16b1 may be a TiC alloy layer and fifth layer 16b2 may be a TiSi alloy layer. The TiC alloy layer has a thickness T_{b1}, for example, not smaller than 100 angstroms and not greater than 500 angstroms, and the TiSi alloy layer has a thickness T_{b2}, for example, not smaller than 100 angstroms and not greater than 500 angstroms. When fourth layer 16b1 is the TiC alloy layer and fifth layer 16b2 is the TiSi alloy layer, loss of Al can be prevented, adhesion with an upper interconnection is enhanced, and mechanical strength can be improved. In composition of the TiC alloy and the TiSi alloy, Ti composition (atomic percent) occupies 5% to 95% and more desirably 30 to 60%.

Referring to FIG. 14, second region 16b may have fourth layer 16b1 formed on first region 16a, fifth layer 16b2 formed on fourth layer 16b1, a sixth layer 16b3 formed on fifth layer 16b, and a seventh layer 16b4 formed on the sixth layer. Each of fourth layer 16b1 and sixth layer 16b3 is, for example, a silicon layer, and each of fifth layer 16b2 and seventh layer 16b4 is, for example, a titanium layer. Namely, second region 16b is constructed such that the silicon layer and the titanium layer are alternately stacked in a direction of normal to first main surface 10a. The silicon layer may be smaller in thickness than the titanium layer. The silicon layer has thickness T_{b1} or T_{b3}, for example, not smaller than 50 angstroms and not greater than 450 angstroms, and the titanium layer has thickness T_{b2} or T_{b4}, for example, not smaller than 50 angstroms and not greater than 450 angstroms. When second region 16b is constructed such that the silicon layer and the titanium layer are alternately stacked in the direction of normal to first main surface 10a, loss of Al can be prevented, adhesion with an upper interconnection is enhanced, and mechanical strength can be improved. In composition of the TiC alloy and the TiSi alloy, Ti composition (atomic percent) occupies 5% to 95% and more desirably 30 to 60%. More desirably, second region 16b has a silicon layer as an eighth layer b5 as an uppermost layer, so that oxidation at a surface is prevented and electrical and mechanical stabilization is achieved.

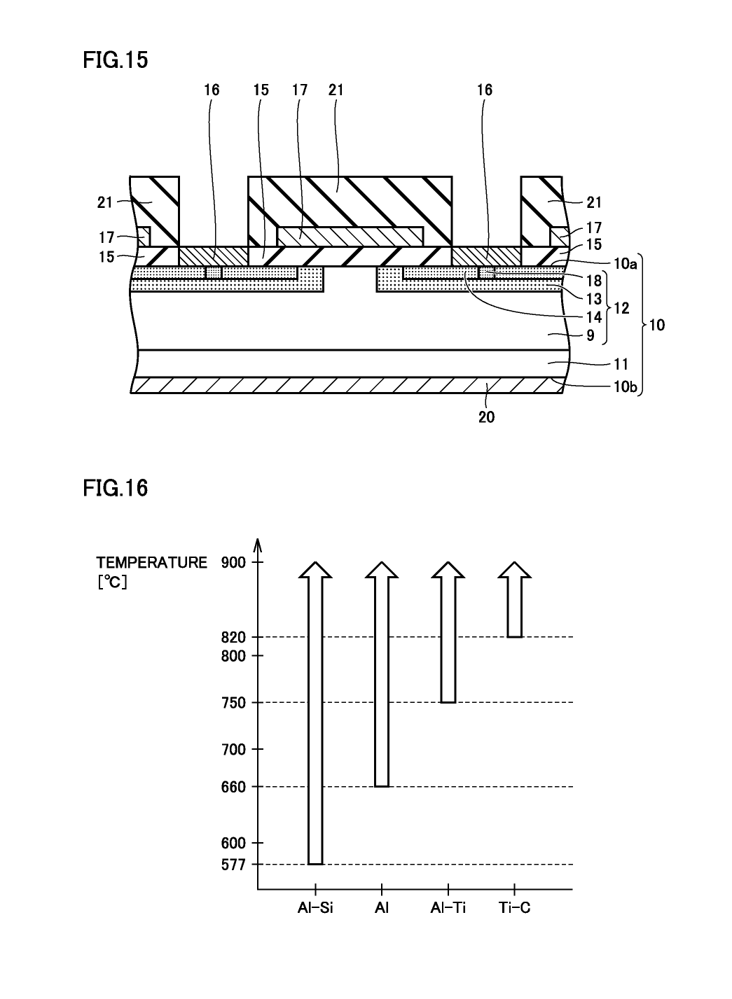

Referring to FIG. 15, in the metal layer forming step (S80: FIG. 2), drain electrode 20 may be formed to be in contact with second main surface 10b of silicon carbide layer 10. Drain electrode 20 is, for example, an Ni electrode.

Then, an annealing step (S100: FIG. 2) is performed. Specifically, after metal layer 16 in contact with p+ region 18 and n+ source region 14 is formed in the metal layer forming step (S80: FIG. 2), p+ region 18, n+ source region 14, and metal layer 16 are annealed. More specifically, silicon carbide layer 10 having metal layer 16 formed is heated from a room temperature to a temperature around 1000° C., for example, in such an inert gas as argon. Thereafter, silicon carbide layer 10 having metal layer 16 formed is held, for example, at a temperature around 1000° C., for example, for approximately 2 minutes. Thus, as metal layer 16 is alloyed with p+ region 18 and n+ source region 14 in the silicon carbide layer, source contact electrode 16 (FIG. 15) is formed. Source contact electrode 16 is in ohmic contact with each of p+ region 18 and n+ source region 14.

Referring to FIG. 16, a reaction temperature zone of Ti, Al, and Si forming source contact electrode 16 in a temperature range, for example, from a room temperature (around 25° C.) to 1000° C. representing an annealing temperature will be described. Initially, a eutectic point of AlSi is around 577° C. and a melting point of Al is around 660° C. Initially, it is expected that reaction between Al and Si takes place at a temperature around 550° C. lower than a temperature around 577° C. representing the eutectic point of AlSi. Liquefaction of AlSi starts at a temperature around 577° C. and liquefaction of Al starts at a temperature around 660° C. Thereafter, it is expected that reaction between Al and Ti takes place at a temperature around 750° C. lower than 820° C. representing a eutectic point of Ti and C. Then, according to the method for manufacturing a MOSFET according to the present embodiment, metal layer 16 in which second region 16b containing Ti is formed on first region 16a containing Al and Si is annealed around 1000° C., so that evaporation of Al from second surface 16b5 representing the surface of metal layer 16 and separation of some Al from metal layer 16 are suppressed.

Then, referring again to FIG. 1, source interconnection 19 and backside pad electrode 23 are formed. Backside pad electrode 23 is formed to be in contact with drain electrode 20. For example, an Ni/Au stack film is employed for backside pad electrode 23. A Ti/Al layer is formed as source interconnection 19, for example, with vapor deposition, so as to be in contact with source contact electrode 16 and to cover interlayer insulating film 21. As above, MOSFET 1 shown in FIG. 1 is completed.

A function and effect of the method for manufacturing MOSFET 1 according to the present embodiment will now be described.

According to the method for manufacturing MOSFET 1 according to the present embodiment, after metal layer 16 in which second region 16b containing the titanium element is arranged on first region 16a having the aluminum element and the silicon element is formed, metal layer 16 is annealed. Therefore, since metal layer 16 is annealed while aluminum is covered with titanium, evaporation of aluminum and separation thereof from metal layer 16 can be prevented. Consequently, MOSFET 1 having source contact electrode 16 capable of realizing a low contact resistance to both of p+ region 18 and n+ source region 14 in silicon carbide layer 10 can be manufactured.

According to the method for manufacturing MOSFET 1 according to the present embodiment, first region 16a further contains the titanium element. Thus, MOSFET 1 having source contact electrode 16 capable of realizing a lower contact resistance to both of p+ region 18 and n+ source region 14 in silicon carbide layer 10 can be manufactured.

According to the method for manufacturing MOSFET 1 according to the present embodiment, in the step of forming first region 16a, first layer 16a1 being in contact with p-type region 18 and n-type region 14 and containing the titanium element is formed. Second layer 16a2 being in contact with first layer 16a1 and containing the aluminum element is formed. Third layer 16a3 being in contact with second layer 16a2 and containing the silicon element is formed. Since third layer 16a3 containing the silicon element is formed on first layer 16a1 containing the aluminum element, evaporation of aluminum can efficiently be suppressed. Consequently, a contact resistance between p+ region 18 and source contact electrode 16 can be lowered.

According to the method for manufacturing MOSFET 1 according to the present embodiment, first layer 16a1 has a thickness not smaller than 140 angstroms and not greater than 340 angstroms. Thus, a contact resistance between source contact electrode 16 and n+ source region 14 and a contact resistance between source contact electrode 16 and p+ region 18 can effectively be lowered.

According to the method for manufacturing MOSFET 1 according to the present embodiment, second layer 16a2 has a thickness not smaller than 190 angstroms and not greater than 390 angstroms. Thus, a contact resistance between source contact electrode 16 and p+ region 18 can effectively be lowered.

According to the method for manufacturing MOSFET 1 according to the present embodiment, third layer 16a3 has a thickness not smaller than 230 angstroms and not greater than 430 angstroms. Thus, a contact resistance between source contact electrode 16 and n+ source region 14 can effectively be lowered.

According to the method for manufacturing MOSFET 1 according to the present embodiment, second region 16b further contains the silicon element. Thus, oxidation of titanium contained in second region 16b can be suppressed. As a result of oxidation of silicon, silicon dioxide is produced, however, silicon dioxide can readily be removed with hydrofluoric acid.

According to the method for manufacturing MOSFET 1 according to the present embodiment, the step of forming second region 16b includes the following steps. Fourth layer 16b1 being in contact with first region 16a and containing the titanium element is formed. Fifth layer 16b2 being in contact with fourth layer 16b1 and containing the silicon element is formed. Thus, oxidation of titanium contained in second region 16b can effectively be suppressed.

According to the method for manufacturing MOSFET 1 according to the present embodiment, the step of forming second region 16b includes the step of forming a layer containing a titanium silicide alloy. Thus, oxidation of titanium contained in second region 16b can effectively be suppressed.

According to the method for manufacturing MOSFET 1 according to the present embodiment, the step of forming second region 16b includes the step of forming a layer containing a titanium carbon alloy. Thus, oxidation of titanium contained in second region 16b can effectively be suppressed.

According to the method for manufacturing MOSFET 1 according to the present embodiment, second region 16b has a thickness not smaller than 200 angstroms and not greater than 300 angstroms. When second region 16b has thickness T_{b} in a range not smaller than 200 angstroms and not greater than 300 angstroms, evaporation of aluminum contained in first region 16a can effectively be suppressed and productivity of MOSFET 1 can be improved.

It should be understood that the embodiment disclosed herein is illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 silicon carbide semiconductor device (MOSFET); 9 drift layer; 10 silicon carbide layer; 10a first main surface (main surface); 10b second main surface; 11 single-crystal substrate; 12 epitaxial layer; 13 p body; 14 n-type region (n+ source region); 15 gate insulating film (thermal oxidation film); 16 metal layer (source contact electrode); 16a first region; 16a1 first layer; 16a2 second layer; 16a3 third layer; 16a4 first surface; 16a5 surface; 16b second region; 16b1 fourth layer; 16b5 second surface; 16b3 sixth layer; 16b4 seventh layer; 16b2 fifth layer; 17 gate electrode; 18 p-type region (p+ region); 19 source interconnection; 20 drain electrode; 21 interlayer insulating film; 22 source electrode; and 23 backside pad electrode.

1. A method for manufacturing a silicon carbide semiconductor device, comprising the steps of:
preparing a silicon carbide layer having a main surface and including a p-type region and an n-type region in contact with said p-type region;
forming a metal layer in contact with said p-type region and said n-type region at said main surface; and
annealing said p-type region, said n-type region, and said metal layer after said step of forming a metal layer,
said step of forming a metal layer including the steps of
forming a first region in contact with said p-type region and said n-type region at said main surface, and
forming a second region arranged to be in contact with a surface of said first region opposite to a surface in contact with said main surface,
said first region having an aluminum element and a silicon element, and
said second region having a titanium element.

2. The method for manufacturing a silicon carbide semiconductor device according to claim 1, wherein
said first region further contains the titanium element.

3. The method for manufacturing a silicon carbide semiconductor device according to claim 2, wherein
said step of forming a first region includes the steps of
forming a first layer being in contact with said p-type region and said n-type region and containing the titanium element,
forming a second layer being in contact with said first layer and containing the aluminum element, and
forming a third layer being in contact with said second layer and containing the silicon element.

4. The method for manufacturing a silicon carbide semiconductor device according to claim 3, wherein
said first layer has a thickness not smaller than 140 angstroms and not greater than 340 angstroms.

5. The method for manufacturing a silicon carbide semiconductor device according to claim 3, wherein
said second layer has a thickness not smaller than 190 angstroms and not greater than 390 angstroms.

6. The method for manufacturing a silicon carbide semiconductor device according to claim 3, wherein
said third layer has a thickness not smaller than 230 angstroms and not greater than 430 angstroms.

7. The method for manufacturing a silicon carbide semiconductor device according to claim 1, wherein
said second region further contains the silicon element.

8. The method for manufacturing a silicon carbide semiconductor device according to claim 7, wherein
said step of forming a second region includes the steps of forming a fourth layer being in contact with said first region and containing the titanium element and forming a fifth layer being in contact with said fourth layer and containing the silicon element.

9. The method for manufacturing a silicon carbide semiconductor device according to claim 7, wherein
said step of forming a second region includes the step of forming a layer containing a titanium silicide alloy.

10. The method for manufacturing a silicon carbide semiconductor device according to claim 1, wherein
said step of forming a second region includes the step of forming a layer containing a titanium carbon alloy.

11. The method for manufacturing a silicon carbide semiconductor device according to claim 1, wherein
said second region has a thickness not smaller than 200 angstroms and not greater than 300 angstroms.
